(19) United States
(12) Patent Application Publication
(10) Pub. No.: US 2018/0076070 A1
(43) Pub. Date: Mar. 15, 2018

(54) PLASMA-TREATMENT DEVICE FOR WAFERS

(71) Applicant: Wilfried Lerch, Dornstadt (GB)

(72) Inventors: Michael Klick, Berlin (DE); Ralf Rothe, Berlin (DE); Wilfried Lerch, Dornstradt/Tomerdingen (DE); Johannes Rehli, Blaubeuren (DE)

(21) Appl. No.: 15/563,647

(22) PCT Filed: Apr. 1, 2016
(86) PCT No.: PCT/EP2016/057285

§ 371 Date: Oct. 2, 2017

(30) Foreign Application Priority Data
Apr. 2, 2015 (DE) 10 2015 004 414.1

(51) Int. Cl. H01L 21/673; C23C 16/509; H01J 37/32

(52) U.S. Cl. CPC H01L 21/67313; H01L 21/67326; H01J 37/32577; H01J 37/32082; C23C 16/509

(57) ABSTRACT

In order to provide an improved introduction of high-frequency waves into a wafer boat, a plasma treatment apparatus for wafers, in particular for semiconductor wafers for semiconductor or photovoltaic applications, is provided, wherein the apparatus comprises a processing room for holding a wafer boat, the wafer boat having a plurality of electrically conductive carrier elements for the wafers, means of controlling or regulating a process gas atmosphere in the processing room, and at least one voltage source which can be connected with the wafer boat by means of a cable fed into the processing room. The cable is in the form of a coaxial cable with an inner conductor and an outer conductor, and a dielectric is provided between the inner conductor and the outer conductor in such a way that, when a high-frequency voltage is applied, the propagation speed and the wavelength of the electromagnetic wave in the coaxial cable is reduced as opposed to the propagation speed and the wavelength of the electromagnetic wave in a vacuum.

### RELATED APPLICATIONS

This application corresponds to PCT/EP2016/057285, filed Apr. 1, 2016, which claims the benefit of German Application No. 10 2015 004 414.1, filed Apr. 2, 2015, the subject matter of which are incorporated herein by reference in their entirety.

### BACKGROUND OF THE INVENTION

The present invention concerns a treatment apparatus for wafers, which is suitable for generating a plasma between wafers held by the apparatus.

In semiconductor and solar cell technology it is well known that disc-shaped substrates made of various materials, which are referred to as wafers in the following, independently of their geometric shape and material, are submitted to various different processes.

In this regard, wafers are submitted frequently to single treatment processes as well as batch processes, that is, processes in which several wafers are treated simultaneously. Both for single processes and for batch processes the wafers must in each case be moved into a desired treatment position, in batch processes this is usually achieved by placing the wafer in so-called boats, which have spaces for a plurality of wafers, in the boats, the wafers are usually placed parallel to one another. Such boats can be built in various different ways, and frequently the design is such that only the bottom edges of the wafers are held in the boat, letting the wafer stand freely upright. Such boats can for example comprise lead-in chamfers so as to facilitate the placement of the bottom edges of the wafers into the boats. Such boats ere usually passive, that is, apart from providing a holding function they have no further function during the processing of the wafers.

In the case of one type of wafer boat, which for example is used for a plasma processing of wafers in semiconductor or solar cell technology, the wafer boat is formed out of a plurality of electrically conductive plates, which are normally made of graphite. The plates are substantially positioned parallel to one another, and carrier slits are formed between adjacent plates for holding the wafers. The sides of the plates which face one another each have corresponding carrier elements for wafers, so that wafers can be inserted at each of these sides. Rods are usually provided al each plate side which faces another plate, and the rods function as earner elements which receive the wafers, in this way, at least two wafers can be completely accommodated in each carrier silt between the plates in such a way that they face each other. Adjacent plates of the wafer boat are electrically insulated from one another, and during the process a high-frequency AC current is applied between directly adjacent plates, usually in the kHz or MHz region, in this way, a plasma can be generated between the plates and in particular between the wafers which are held at the respective plates, in order to provide a plasma treatment such as for example a plasma deposition or a plasma nitriding of films. It has been shown that the application of a high-frequency AC current. In particular in the MHz range, is frequently associated with high losses, which can in some cases prevent the ignition of a plasma between the wafers.

The aim of the present invention is to provide a plasma treatment apparatus for wafers which enables an improved application of the high-frequency AC current.

According to the invention, this aim is achieved by a plasma treatment apparatus according to claim 1. Further embodiments of the invention may be derived inter alia from the dependent claims.

In particular, a plasma treatment apparatus for semiconductor wafers for semiconductor or photovoltaic applications is provided, and has a processing room for holding a wafer boat with a plurality of electrically conductive carrier elements for the wafers, means of controlling or regulating a process gas atmosphere in the processing room and at least one voltage source which can be connected with the wafer boat by means of a cable fed into the processing room. The cable is in the form of a coaxial cable with an inner conductor end an outer conductor, and between the inner conductor and the outer conductor a dielectric is provided in such a way that, when a high-frequency voltage is applied, the propagation speed and the wavelength of the electromagnetic wave in the coaxial cable is reduced as opposed to a corresponding propagation speed and wavelength of the electromagnetic wave in a vacuum. The above-described apparatus enables an improved introduction of high-frequency waves into a wafer boat in a plasma treatment apparatus.

Preferably the geometrical length of the coaxial cable should be near to an odd-numbered multiple of λ/4 of the wavelength which was reduced by the dielectric, in an embodiment, the dielectric is formed of a plurality of dielectric elements, which results in a simple construction. Preferably, the dielectric is formed of a plurality of dielectric elements with different dielectric constants, which are preferably layered in the direction of propagation, which enables the adjusting of a desired effective real dielectric constant of the dielectric.

The at least one voltage source is preferably of the type which is adapted to generate a high-frequency AC current, in particular with a frequency in the MHz range and particularly in the range of 13.56 MHz.

### BRIEF DESCRIPTION OF THE DRAWINGS

The invention will now be described in more detail with reference to the drawings; in the drawings:

FIG. 1 shows a schematic side view of a wafer boat;

FIG. 2 shows a schematic top view onto the wafer boat according to FIG. 1;

FIG. 3 shows a schematic front view of a wafer boat according to FIG. 1;

FIG. 4 shows a schematic view of a plasma treatment apparatus with the wafer boat according to FIG. 1 held therein;

FIG. 5 shows a schematic front view of a process chamber of the plasma treatment apparatus according to FIG. 4;

FIG. 6 shows a schematic top view onto a part of the gas supply of the process chamber according to FIG. 5;

FIG. 7 shows a schematic front view of an alternative process chamber of the plasma treatment apparatus according to FIG. 4;

FIG. 8 shows a schematic front view of a further alternative process chamber of the plasma treatment apparatus according to FIG. 4;

FIG. 9 shows a schematic front view of a further alternative process chamber of the plasma treatment apparatus according to FIG. 4;

FIG. 10 shows a schematic side view of an alternative wafer boat for use in a plasma treatment apparatus;

FIG. 11(a) to (c) show schematic side views of parts of the alternative wafer boat according to FIG. 9, separately and in their final composition;

FIG. 12 shows a schematic top view onto a section of the wafer boat according to FIG. 9;

FIG. 13 shows a schematic side view of a further alternative wafer boat for use in a plasma treatment apparatus; and

FIG. 14 shows a schematic side view of a part of the alternative wafer boat according to FIG. 12;

FIG. 15 shows a schematic top view onto a further alternative wafer boat;

FIG. 16 shows a schematic side view of a part of the wafer boat according to FIG. 15;

FIG. 17(a) and (b) show schematic cross-sectional views through a process chamber of a plasma treatment apparatus according to FIG. 4 with a wafer boat according to FIG. 15 held therein;

FIG. 18 shows a schematic top view of a further wafer boat;

FIG. 19 shows a schematic side view of a portion of the wafer boat according to FIG. 19; and

FIG. 20(a) and (b) show schematic cross-sectional views through a process chamber of a plasma treatment apparatus according to FIG. 4 with a wafer boat according to FIG. 18 held therein.

### DESCRIPTION

Terms used in the description, such as “above”, “below”, “left” and “right”, relate to the drawings and are not to be intended to be restricting. They can however describe preferred embodiments. The term “substantially” relating to parallel, vertical or angle measurements should include deviations of ±3°, preferably ±2°. In the following descriptions the term “wafer” will be used for disc-formed substrates, which are preferably semiconductor wafers for semiconductor or photovoltaic applications, although substrates made of other materials can also be provided and processed.

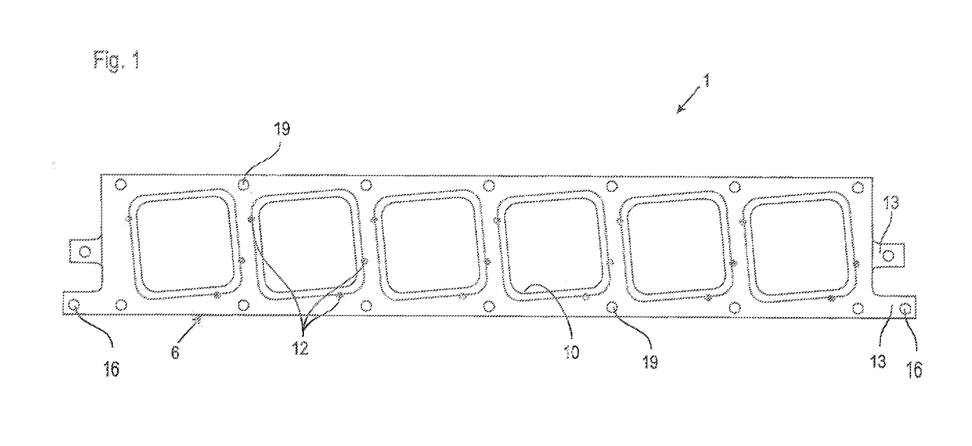

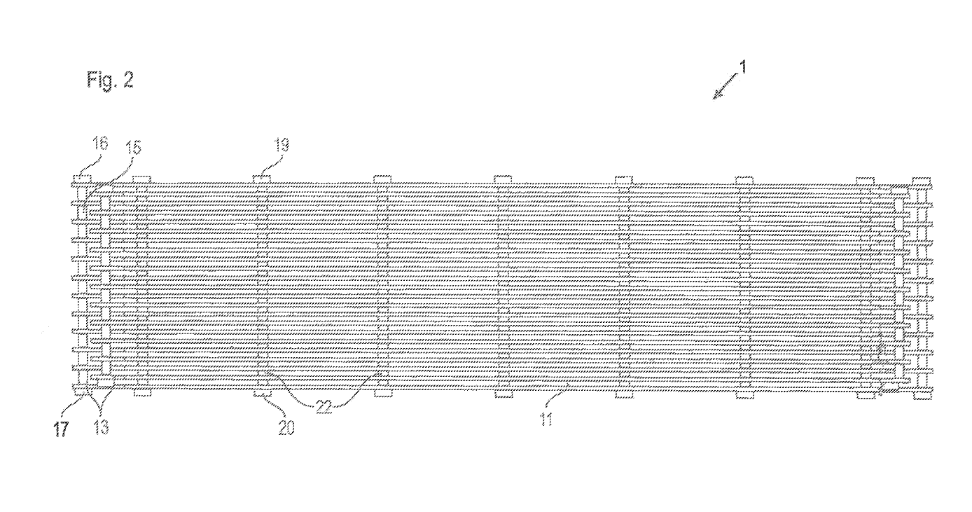

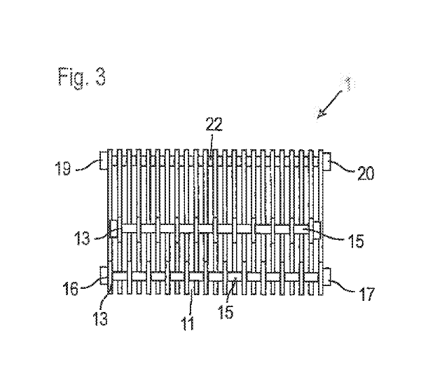

In the following descriptions the basic structure of a wafer boat 1 for use in a plasma treatment apparatus will be more closely described with reference to FIGS. 1-3, wherein FIG. 1 shows a schematic side view of a wafer boat 1 and FIGS. 2 and 3 show a top view and a front view. In the figures the same reference signs will be used inasmuch as they describe the same or similar elements.

The wafer boat 1 is composed of a plurality of plates 6, contacting elements 7 and clamping units 8. The pictured wafer boat 1 is particularly suitable for a coating deposition from a plasma, e.g. of Si₃N₄, SiNₓ, a-Si etc. and in particular for the plasma nitriding of wafers.

The plates 6 each consist of an electrically conductive material and in particular they are formed as graphite plates, although, depending on the process, a coating or surface treatment of the plate basic material can be carried out. The plates 6 each have six apertures 10 which are covered by the wafers during the process, as will be described in more detail hereafter. Although in the depicted form six apertures per Plate 6 are provided it should be noted that a larger or smaller number of apertures can be provided. The plates 6 each have upper and lower edges, wherein in the upper edge e.g. a plurality of notches can be formed. In order to facilitate the position detection of the plates, such as is described in DE 10 2010 025 483.

In the depicted embodiment there are in total 23 plates 6, which are substantially arranged in parallel to one another by means of corresponding contact units 7 and clamping units 8, in order to form carrier silts 11 between them. In the case of twenty-three plates 6 there are twenty-two carrier slits 11. In practice however, 19 or 21 plates are frequently used, and the invention is not restricted to a particular quantity of plates.

The plates 6 have, at least on their respective side which faces an adjacent plate 6, groups of three respective carrier elements 12 which are positioned in such that they can receive a wafer between them. The groups of the carrier elements 12 are each positioned around each aperture 10, as schematically indicated in FIG. 1. The wafers can be inserted in such a way that the carrier elements in each case come into contact with a different side edge of the wafer, in the lengthways direction of the plate elements (corresponding to the apertures 10) there are in total six respective groups of carrier elements provided for the reception of a semiconductor wafer.

At the ends of plates 6 there is in each case a protruding contact nib 13 which serves for electrically contacting the plates 6, as will be more closely described hereafter. Two embodiments of plates 6 are provided, which differ in the position of the contact nibs 13. In one embodiment, the contact nibs 13 respectively protrude directly adjacent to the bottom edge, whereas in the other embodiment they protrude at a distance from the bottom edge, wherein the distance to the bottom edge is greater than the height of the contact nibs 13 of the plates of the other embodiment. The two embodiments of plates 6 are positioned in an alternating manner in the wafer boat 1. As can most clearly be seen in the view according to FIG. 2, the contact nibs 13 of directly adjacent plates 6 lie on different levels in the wafer boat apparatus. In the case of every second plate 6, the contact nibs 13 are however on the same level, in this way, two spaced contact levels are created by means of the contact nibs 13. This apparatus enables directly adjacent plates 6 to be supplied with different potential, while every second plate can be supplied with the same potential.

The contact nibs 13 which lie on one contact level are electrically connected by means of contact blocks 15, made of a material of good electrical conductivity, in particular graphite, and are positioned at a predetermined distance from one another. In the region of the contact nibs 13 and in each of the contact blocks 15 at least one through opening is provided. These enable the insertion of a clamping element 16 when they are lined up, which has a shaft section (not visible) and a head section, such as e.g. a screw. By means of a counter element, such as a nut 17, which acts or sits on the free end of the shaft section the plates 6 can be fixed to one another. The plates are fixed together in two different groups in such a way that the plates of the different groups are positioned in alternation. The clamping element 16 can be made of an electrically conductive material, but this is not obligatory. The contact blocks 15 each have preferably the same length (in the direction which defines the distance between the contact nibs 13 of the plates 6) and this should equal the width of two carrier silts 11 plus the width of one plate 6. The contact blocks 15 are preferably designed in such a way that they have a low thermal mass and in particular the sum of the contact blocks should have a lower thermal mass than the sum of the plates 6. More preferably, the combined thermal mass of the sum of the contact blocks and the sum of the contact nibs 13 of the plates should be smaller than the thermal mass of the sum of the plates 6 minus the thermal mass of the contact nibs 13.

In addition, further through openings are provided in the plates adjacent to the upper edge and the lower edge, wherein the through openings allow the insertion of a clamping element 19 which has a shaft section (not visible) and a head section, such as e.g. a screw of the clamping unit 8. These can in turn be combined with suitable counter elements 20 such as e.g. nuts. In the depicted embodiment, there are in each case seven through openings adjacent to the upper edge and seven through openings adjacent to the lower edge. Around each aperture 10 there are positioned, virtually symmetrically, four through openings. As a further part of the clamping unit there is provided a plurality of spacing elements 22, which are e.g. in the form of spacer sleeves with substantially the same length. The spacing elements 22 are positioned in each case in the region of the corresponding through openings between the directly adjacent plates 6,

The respective shaft sections of the clamping elements 19 are sized in such a way that they can extend through corresponding openings of all plates 6 as well as through the spacing elements 22 which are situated between the plates. In this way, by means of the at least one counter element 20, all plates 6 can substantially be fixed parallel to one another. Here, other clamping units could be conceivably used with spacing elements 22, which line up and clamp the plates 6 with the spacing elements 22 in a substantially parallel manner. In the depicted embodiment, there are 22 carrier slits and in total 14 spacing elements 22 per slit (seven at the upper edge and seven at the lower edge), making a total of 308 spacing elements.

The clamping elements 19 are preferably made of an electrically insulating material, but the spacing elements 22 should be preferably made of an electrically conductive material. In particular, the spacing elements 22 should be made of a high-resistance material such that the spacing elements can serve as a resistance element when a DC current or a low-frequency AC current with sufficient amplitude is supplied, but when a high-frequency AC current is supplied (for the generation of a plasma between the plates) that there is no significant damping of the wave propagation. For a low-frequency current, a frequency range of 50 Hz-10 KHz is considered. For the high-frequency current a frequency range of mere than 40 KHz is considered, specifically in the rage of more than 1 MHz, more specifically in the rage of 13.56 MHz, although also other frequency ranges would be possible. In the depicted embodiment with the selected distribution, each spacing element should have a resistance of e.g. 3 kΩ. In particular more than 20 kΩ or even more than 40 kΩ. For example the spacing elements can be made of doped silicon, polysilicon or another suitable material, which on one hand is not affected by the process and on the other side does not affect the process, and in particular does not introduce any impurities into the process. While the plates 6 of one group (upper contact nibs 13/lower contact nibs 13) are electrically connected and fixed to one another via contract elements 15, all plates are electrically connected and fixed to one another by means of the spacing elements 22.

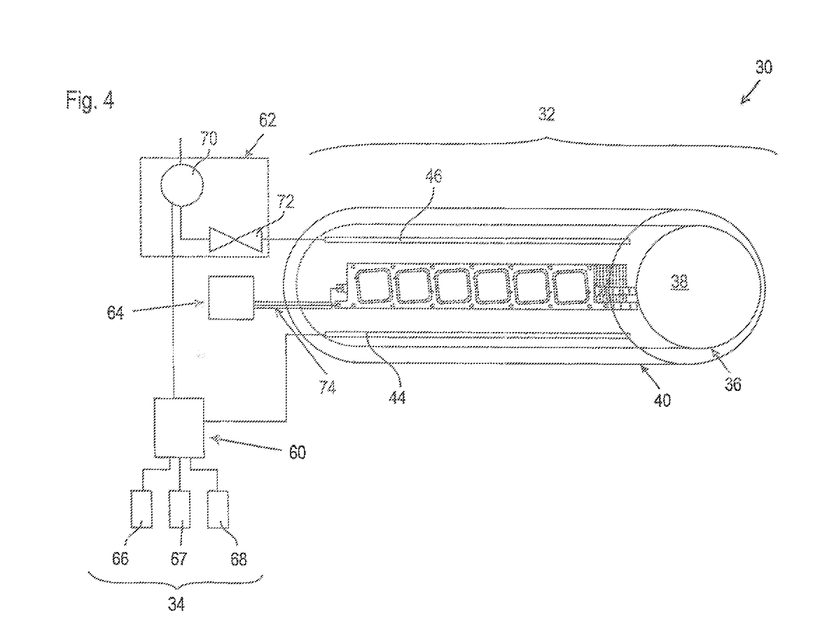

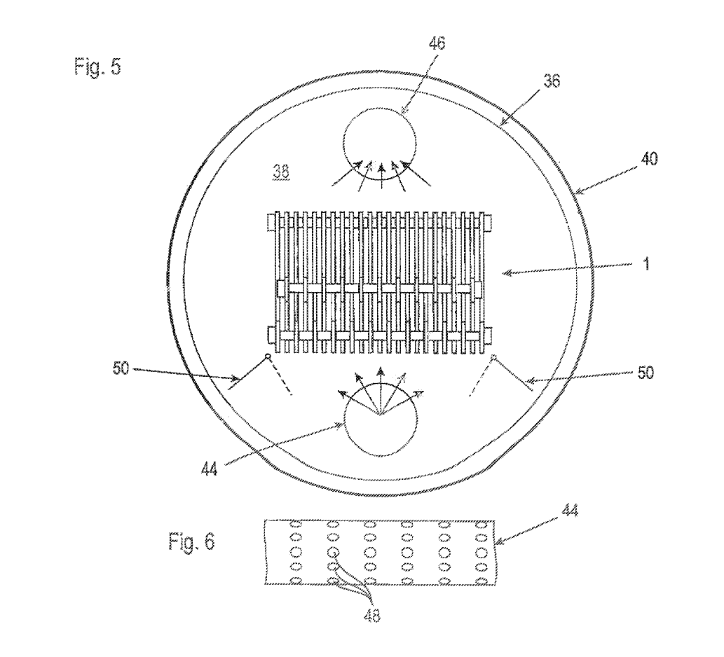

In the following, the basic structure of a plasma treatment device 30, in which a wafer boat 1 of the above-mentioned type can be used (but also a conventional wafer boat), will be described in more detail referring to FIGS. 4 to 6, wherein FIG. 4 shows a schematic side view of the treatment apparatus 30, FIG. 5 shows a schematic front view of a process chamber construction and FIG. 6 shows a top view onto a gas supply.

The treatment apparatus 30 comprises a process chamber section 32 and a control section 34. The process chamber section 32 comprises a pipe element 36 closed on one side which forms in its interior a process chamber 38. The open end of the pipe element 36 serves for loading the process chamber 38, and it can be shut and hermetically sealed by means of a closing mechanism (not shown), as is known in this field of technology. The pipe element is made of a suitable material which does not introduce impurities into the process, is electrically insulated and can withstand the process conditions with regard to temperature and pressure (vacuum), such as e.g. quartz. At its closed end, the pipe element 36 comprises gas-tight passages for the introduction and removal of gases and electricity, which can be designed in the usual manner. Corresponding supply-lines and discharge-lines could however be situated at the other end or even also at the side at a suitable position between the ends.

The pipe element 36 is surrounded by a jacket 40 which isolates the pipe element 36 thermally from its environment. Between the jacket 40 end the pipe element 36 a heating device is provided (not shown in detail), such as a resistance heater, which is suitable for heating up the pipe element 36. However, such a heating device can e.g. also be situated in the interior of the pipe element 36, or the pipe element 36 could itself be designed as a heating element. At the present time, however, an externally situated heating element is preferred and, in particular, one which comprises different, individually controllable heating circuits.

In the interior of the pipe element 36 are situated carrier elements (not shown in more detail) which form a holding level for holding a wafer boat 1 (which is only partially shown in FIG. 4), which can e.g. be of the above-described type. The wafer boat can however also be placed in the pipe element 36 in such a manner that it stands on the wall of the pipe element 36. In this case the wafer boat will be substantially held above the reception level and is positioned more or less centrally in the pipe element, as can be seen e.g. in the front view in FIG. 5. Using suitable carrier elements and/or a direct placement on the pipe element, a carrier space is defined in combination with the measurements of the wafer boat, in which is situated a properly inserted wafer boat. The wafer boat can be inserted into and extracted from the process chamber 38 as a whole in a loaded state by means of a suitable handling mechanism (not shown). In this case, an electrical contact with at least one contact block 15, respectively, of each of the group of plates 6 will be made, when the wafer boat is loaded, as will be described in more detail hereafter.

In the interior of the pipe element 38 are situated additionally a lower gas supply pipe 44 and an upper gas supply pipe 46, which are made of a suitable material such as quartz. The gas supply pipes 44, 46 extend in a lengthways direction of the pipe element 36 at least along the length of the wafer boat 1. The gas supply pipes 44, 46 each have a round profile and are situated in transverse direction approximately centrally above or below the wafer boat 1. The gas supply pipes 44, 46 are connected with a gas supply unit or gas exhaust unit at their end which is nearer to the closed end of the pipe element 36, as will be explained in more detail hereafter. The respective other end of the gas supply pipes 44, 46 is closed. One could however consider also a short gas supply, in which case e.g. gas is pumped in only at one end of the pipe element and is distributed by means of diffusion and/or is pumped by a vacuum port (preferably attached at the opposite end of the pipe element 38).

The lower gas supply pip(r) 44 has a plurality of openings 48 through which gas can exit the gas supply pipe. The openings are all situated in the upper half of the gas supply pipe, so that a gas, which is emitted from this pipe, has a momentum which is directed in an upward direction. In particular it is considered to provide a plurality of rows of openings 48 which extend transversely to the lengthways extent of the gas supply pipe 44, wherein every row has e.g. five openings 48. In the top view according to FIG. 6, a section of a corresponding gas supply pipe 44 is shown schematically. The openings should be situated lengthways in a region of the gas supply pipe 44, which is at least as long as the wafer boat. Preferably, the region is longer than the length of the wafer boat and is situated in such a way that the region extends beyond the ends of the wafer boat. Preferably, the sum of the surface area of the openings 48 is smaller than the cross-sectional area of the gas supply pipe 44. Preferably, the relationship between the sum of the surface area of the openings 46 and the cross-sectional area of the gas supply pipe 44 is between 30 and 70% and in particular between 40 and 60%. When a gas is supplied, a constant pressure is created in the gas supply pipe 44, and a uniform gas distribution can be achieved across the area populated with openings. In particular, when the diameter of each opening is approximately 1.5 mm, it should be considered to space the rows of openings 48 by approximately 5 mm. This measurement extends between the central points of each opening of the different rows. The distance can however also be different and in particular in the case of lower pressures, the distance can be larger. A distance of less than 5 cm should be preferred, still more so a distance of less than 2 cm, and particularly one of less than 1 cm.

The upper gas supply pipe 46 has a similar construction with openings, although the openings in this case are situated in the lower half. Essentially, the gas supply pipes 44, 46 can be identically situated, apart from the fact that the orientation is different, so that the openings in each case point towards the wafer boat. Thus, the openings in the lower gas supply pipe 44 and the openings in the upper gas supply pipe 46 point to the carrier region, that is, the region in which a properly inserted wafer boat has been situated. Instead of providing rows of five openings in each row, it is also possible to provide a different layout or also different shapes of openings, e.g. silts.

By means of such gas supply pipes 44, 46 a good, homogeneous gas distribution can be achieved within the process chamber, in particular also in the carrier slits 11 of the wafer boat. To achieve this, it is preferable that the lower gas supply pipe 46 is supplied with gas, while correspondingly gas is removed by means of the upper gas supply pipe 44. The lower gas supply pipe 44 allows a good distribution of gas below the wafer boat and the removal at the upper gas supply pipe 46 allows the gas between the plates 6 of the wafer boat 1 to be moved upwards.

In order to enhance this effect, that is, to direct the gas flow in particular between the plates 6 of the wafer boat, there are two optional, moveable deflection elements 50 provided in the process chamber. The deflection elements 50, which are not shown in FIG. 4, for reasons of simplification of the picture, have an elongated configuration. The deflection elements 50 extend in a lengthways direction of the process pipe 36 and are preferably at least as long as the wafer boat. But preferably the deflection elements 50 should be at least as long as the region of the lower gas supply pipe 44, in which the openings 48 are situated. The deflection elements 50 are situated below the wafer boat and in transverse direction lateral to the wafer boat 1 in the process chamber 38. At their upper end, the deflection elements 50 are each pivotably supported and can be moved by means of an adjustment mechanism (not shown) between a first position, which is shown in FIGS. 5 and 7-9 with a solid line, and a second position, which is shown in FIGS. 5 and 7-9 with a dashed line, in the first position, the deflection elements basically prevent a gas flow around the sides of the wafer boat, while such a gas flow is allowed in the second position.

The adjustment mechanism can e.g. be a mechanism which reacts to pressure in the process chamber 38, which e.g. moves the deflection elements 60 automatically to the first position in the case of a certain negative pressure in the process chamber 38. Other adjustment mechanisms are however conceivable, which are operated mechanically or electrically, although suitable supply lines for controlling them must be provided.

FIGS. 7-9 show schematic front views of alternative process chamber constructions, which differ solely in respect of the form and/or number of gas supply pipes. In the embodiment according to FIG. 7, two lower and two upper gas supply pipes are provided. The lower gas supply pipes 44, 44 are situated in a horizontal level below the wafer boat 1 and are symmetrically positioned with regard to a vertical mid-level of the process chamber. With regard to the openings, they can be constructed and arranged in the same way as the above described gas supply pipe. The upper gas supply pipes 46, 46 are situated on a horizontal level above the wafer boat 1, and they are also symmetrically positioned with regard to a vertical mid-level of the process chamber, in particular in the case of this construction or a similar construction having several lower gas supply pipes for supplying gas, different gases can be fed into the process chamber 38 via different gas supply pipes, so that the gases are not mixed until they are in the process chamber, in order to avoid a premature reaction within the gas supply.

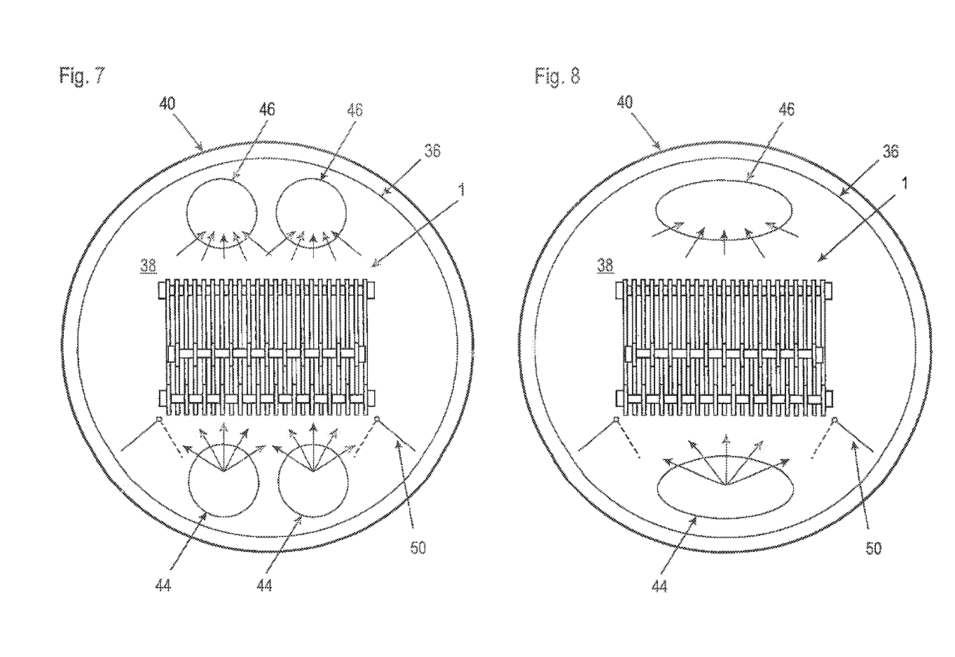

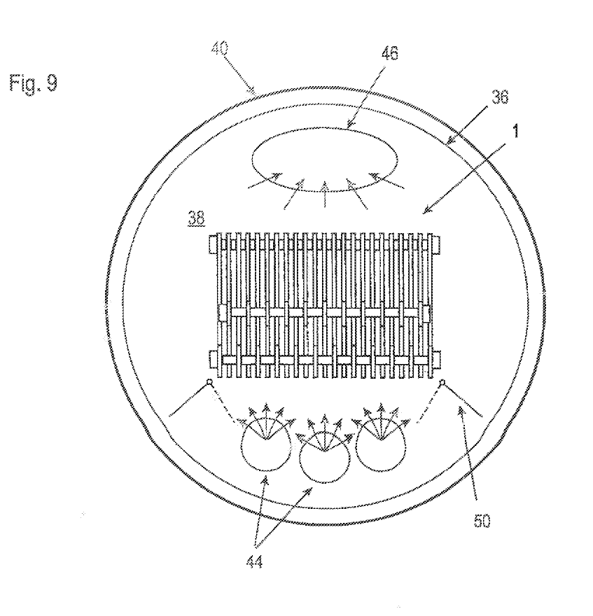

However in the embodiment according to FIG. 8, only one lower and one upper gas supply pipe 44, 46 is provided. The gas supply pipes 44, 46 each have an elliptical cross-sectional shape, wherein the main axes are horizontally positioned. Again, the gas supply pipes 44, 46 are situated centrally below and above the wafer boat 1, respectively. In other words, they are situated symmetrically with respect to a vertical mid-level of the process chamber With regard to the openings, they can be constructed and arranged in the same way as the above described gas supply pipe.

In the case of the embodiment according to FIG. 9, three lower gas supply pipes 44 and one single upper gas supply pipe 46 are provided. The lower gas supply pipes 44 are situated below the wafer boat 1, wherein the two outer ones are at one level and the middle one is at a slightly lower level. However, another arrangement would be possible. With regard to the openings, they can be constructed and arranged in the same way as the above described gas supply pipe. The upper gas supply pipe 46 is situated above the wafer boat 1 and has an elliptical cross-sectional shape, as in FIG. 8, and it is situated symmetrically with respect to a vertical mid-level of the process chamber. Alternatively, several gas supply pipes or another shape of the gas supply pipe could be used here, in particular in the case of this construction or a similar construction having several lower gas supply pipes for supplying the gas, different gases can be fed into the process chamber 38 through different gas supply pipes, so that the gases are not mixed until they are in the process chamber, in order to avoid a premature reaction within the gas supply, in particular, in the case of this arrangement, a first gas can be fed in by means of the outer gas supply pipes 44, while a second gas is fed in by means of the middle gas supply pipe. The arrangement allows a good and homogeneous mixing and distribution of the gases.

Now the control section 34 of the treatment apparatus 30 will be described in more detail. The control section 34 has a gas control unit 60, a negative pressure control unit 62, an electrical control unit 64 and a temperature control unit (not shown in more detail), which can all together be controlled by means of a high-level controller, such as a processor. The temperature control unit is connected to the heating unit (not shown) in order primarily to control or regulate the temperature of the pipe element 36 or the process chamber 38.

The gas control unit 60 is connected with a plurality of different gas sources 66, 67, 66 such as for example gas canisters containing different gases, in the depicted form, three gas sources are shown, although of course any other number of gas sources can be provided. For example, the gas sources can provide at the respective openings of the gas control unit 60 di-chlorsilane, trichlorsilane, SiH₄, phosphine, borane, di-borane, germane (GeH₄), Ar, H₂, TMA NH₃, N₂ and other different gases. The gas control unit 60 has two outlets, one of which is connected with the lower gas supply pipe 44, and the other of which is connected with a pump 70 of the negative pressure control unit 62. The gas control unit 60 can connect the gas sources in a suitable manner with the outlets and can control the throughflow of gas, as is well known in this field of technology, in this way, the gas control unit 60 can direct different gases into the process chamber in particular by means of the lower gas supply pipe 44, as will be described hereafter.

The negative pressure control unit 62 basically comprises the pump and a pressure control valve 72. The pump 70 is connected via the pressure control valve 72 with the upper gas supply pipe 48 and can by means of this pump the process chamber to a predetermined pressure. The connection from the gas control unit 60 to the pump also serves to dilute process gas which is pumped out of the process chamber if necessary with N₂.

The electrical control unit 64 comprises at least one source of electricity which is suitable for providing at one output thereof at least one of the following: a DC current, a low-frequency current and a high-frequency current. The output of the electrical control unit 64 is connected with a cable to a contact unit for the wafer boat in the process chamber.

The cable is inserted by means of a suitable vacuum- and temperature resistant passage way through the jacket 40 and into the pipe element 36. The cable is built in such a way that it is in the form of a coaxial cable 74 with an inner conductor and an outer conductor. Along the length of the coaxial cable 72 there is at the outside approximately zero electromagnetic field, so that, even in the case of high frequencies in the MHz range (e.g. at 13.56 MHz), no parasitic plasmas are generated and that the transmission is lossless as far as possible. In the interior of the coaxial cable there is a wave propagation with wavelength λ. The wave propagation proceeds between pairs of plates (planar waveguide), although with another wavelength, which is dependent on the presence and type of plasma.

Between the conductors of the coaxial cable 74 there is a suitable dielectric, which, when supplied with a high-frequency voltage, lowers the propagation speed and the wavelength of the electromagnetic wave in the coaxial cable as opposed to a corresponding propagation speed and wavelength of the electromagnetic wave in the vacuum. The lowering of the propagation speed and wavelength of the electromagnetic wave in the coaxial cable as opposed to a corresponding propagation speed and wave length of the electromagnetic wave in the vacuum is equivalent to an increase of the effective electrical length of the coaxial cable 74 with respect to the wavelength in a vacuum. In particular in the case of a impedance transformation owing to the low impedance of the wafer boat 1, the geometrical length of the coaxial cable should be near to an odd-numbered multiple of λ/4 of the wavelength which was reduced by the dielectric, or, in other words, the effective electrical length of the coaxial cable should be set at approximately an odd-numbered multiple of λ/4 of the wavelength of the supplied frequency.

In one embodiment, an adjustment of the wavelength or electrical length of the coaxial cable 74 is achieved by means of a plurality of insulators which can be introduced into the gap between the interior conductor and the exterior conductor and thus form the dielectric. A certain degree of adjustment can also be achieved by means of the geometry of the interior conductor and the exterior conductor. Although the interior conductor and the exterior conductor of the coaxial cables usually have a round cross section, the term coaxial cable, as used in the present application, should also include interior and exterior conductors with other cross sections. For example, the interior conductor and/or the exterior conductor can have rectangular or oval cross sections and extend along a common longitudinal axis. The local propagation speed of the high-frequency wave, and altogether therewith the effective electrical length of the coaxial cable 74, is substantially dependent on the dielectric between the interior conductor and the exterior conductor. With an increasing dielectric constant, the propagation speed declines at a rate of 1/(εᵣ)^{1/2} and, accordingly, the effective electrical length of the coaxial cable 74 rises at the same rate. By means of a suitable serial layout of short insulator pieces of differing dielectric constant along the length, a desired medium dielectric constant can be achieved, in particular, it is considered to insert a suitable selection of insulator pieces from a set of two to four different insulator pieces having differing dielectric constants into the gap between the interior conductor and the exterior conductor so as to adjust a desired effective dielectric constant for the dielectric. The insulator pieces can have a shape which is suitable for the interior and exterior conductors, such as e.g. a ring shape, which allows sliding them along the interior conductor. The coaxial cable 74 extends substantially to the contact sections of the wafer boat 1. The interior conductor and the exterior conductor era contacted in a suitable manner with the different groups of plates 6.

The wave propagation between the plate pairs influences the characteristics of the generated plasmas, for example in the homogeneity/uniformity above the wafers and the wafer boat.

To this end, the contact nibs 13 of the wafer boat 1 should be reduced as much as possible in mass and length for introducing high-frequency power, in order to keep the local heat capacity and the inductance of the supply path as low as possible. In particular, the inductance of the supply path formed by the sum of the contact nibs 13 in combination with the contact elements 15 should be substantially smaller than the inductance of the sum of the plates 6. Preferably, the inductance of the corresponding inductance of the supply path at operating frequency should be less than half and preferably less than 1/10 of the inductance of the plate stack of plates 6.

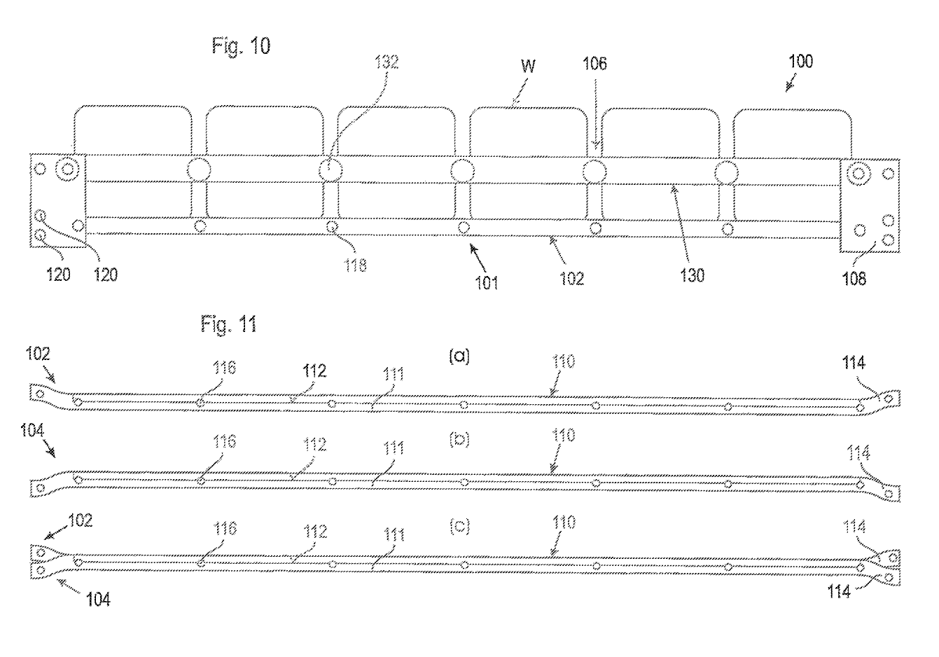

The FIGS. 10-12 show an alternative wafer boat 100 which can be used in a plasma treatment apparatus 30 of the above-described type but can also be used in classical plasma treatment apparatuses. The wafer boat 100 comprises an electrically conductive support assembly 101 with a plurality of electrically conductive supports 102, 104, made e.g. of graphite or another electrically highly conductive material, and an insulated guide unit 106. The support assembly 101 and the insulated guide unit 106 are connected by means of insulated connection elements 108 and together form the wafer boat 100.

The electrically conductive supports 102, 104 can best be seen in the schematic side views of FIGS. 11a to 11c. FIG. 11a shows a schematic side view of the support 102, FIG. 11b shows a schematic side view of the support 104, and FIG. 11c shows a schematic side view of supports 102, 104 in a final position.

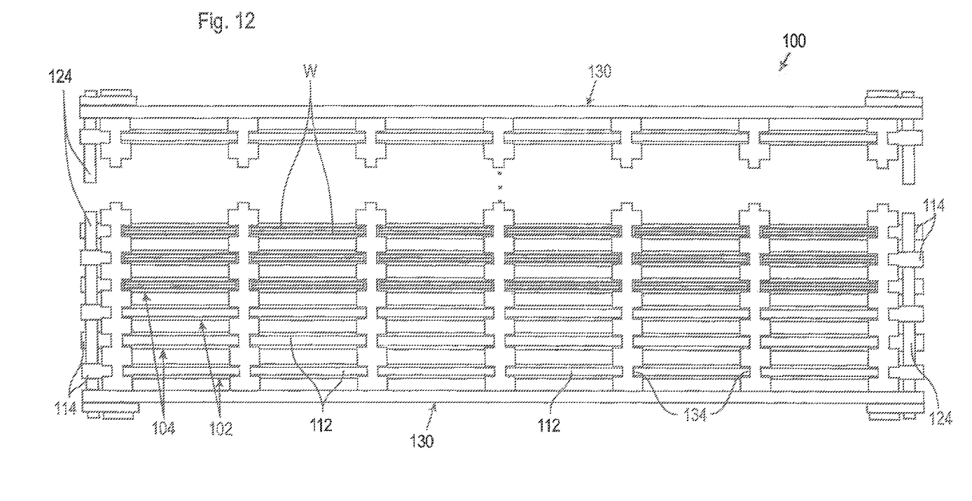

The supports 102, 104 each have an elongated basic body 110 which has a substantially rectangular profile. The basic body 110 has in each case a straight middle part, in the top side of which there is a slit 112 for the reception of wafers (W). In the lengthways direction, the silt 112 is sized in such a way that it can receive six wafers (W) next to one another at predetermined intervals, as can be seen in FIG. 10. The depth of the slit is selected so that if is smaller than or equal to a normal edge waste zone formed in the wafer manufacture, and is generally approximately 1-5 mm. The width of the slit is in turn selected to allow two wafers requiring treatment (W) to be inserted back-to-back, as is indicated in the top view according to FIG. 12. The slit 112 can be inclined transversely at 1°-2° in relation to the lengthways direction, so that a wafer pair inserted therein stands slightly tilted in the slit 112. At their lengthwise ends (adjacent to the middle section 111 which features the slit 112) each of the basic bodies 110 has end sections 114 which are offset in relation to the middle section 111 to a level upwards or downwards. The end sections 114 of the support 102 are offset upwards, and the end sections 114 of the support 104 are offset downwards, as can easily be seen in FIGS. 11a and 11b. When the supports 102, 104 are in the end position, the end sections 114 of the supports 102 lie on an upper level and the end sections 114 of the supports 104 lie on a lower level, as can be seen in FIG. 11c.

In the basic bodies 110 there is in each case a plurality of cross-bores 116 which serve for the insertion of clamp elements 118 and 120. These can be of the type described above with a head and shaft section, which can cooperate with counter elements. The clamp elements 118 are used in the middle section 111, whereas the clamp elements 120 are used in the region of the end sections 114.

In their end position there is a plurality of the supports 102, 104 (e.g. 22) positioned parallel to one another transversely to their lengthwise direction, wherein the supports 102 and 104 alternate in the layout. In the middle section 111 of the supports 102, 104, spacers (not shown) are provided between directly adjacent supports 102, 104 which are lined up with the cross-bores 116. These spacers are sleeve-shaped and dimensioned such that they are put onto the shaft section of the clamp element 118 in an assembled condition of the wafer boat 100. The spacers can be electrically insulating or electrically conductive, as are the above described spacing elements 22 of the wafer boat 1, inasmuch as they should perform a similar heating function.

In the region of the end sections 114 are provided in each case electrically conductive sleeves 124 which are so dimensioned as to be able to be put onto the shaft section of one of the clamp elements 120. The length of each of the sleeves is the length of two spacers plus the width of a support. in this way they can each electrically connect two supports 102, 102 or 104, 104 in the arrangement. In this way, the supports 102 form a first group of supports which are all electrically connected with each other, and the supports 104 form a second group of supports which are all electrically connected with each other. This in turn allows to apply a voltage to the different groups, as also in the case of wafer boat 1.

The guide unit 106 comprises two elongated holding elements 130 and seven guiding rods 132, which are all made of a dielectric material. The holding elements 130 and the guiding rods 132 can e.g. be made of ceramic or quartz. The holding elements 130 each have an elongated configuration and have the same length substantially as the length of supports 102, 104, and they extend substantially parallel to supports 102, 104, wherein the holding elements 130 are positioned higher than the supports 102, 104. The guiding rods 132 extend perpendicularly between the holding elements 130, as can be seen in the top view according to FIG. 12, and they are connected in a suitable manner with them. The guiding rods 132 can have a circular cross section, although other shapes are also possible. The guiding rods 132 each have a plurality of notches 134 which are dimensioned so that they can receive and guide an edge area of wafer pairs W, W, in particular a waste-edge area, in a lengthwise direction of the wafer boat 100 the guiding rods 132 are spaced in such a way that they can each receive a wafer pair W, W between them, as is indicated in FIG. 12. At this point it should be noted that the top view according to FIG. 12 does not show the wafer boat 100 completely, and that the wafer boat is only partially loaded, for reasons of simplifying the picture. The notches 134 are lined up with the slots 112 in the supports 102, 104 in a transverse direction of the wafer boat 100. inasmuch as the slits 112 have an inclination, the notches 134 are correspondingly slightly offset with respect to the slits 112, in order to allow to hold the wafer pairs W, W in a slightly inclined position.

The support unit 101, consisting of the connected supports 102, 104, and the insulated guide unit 106, consisting of the support elements 130 and guide rods 132, are each connected in the end sections by means of insulated connecting dements 108. In particular, the connecting elements 108 have a plate shape and they cooperate with the clamp elements 118 and 120 and further clamp elements for the connection with holding element 130, in order to fix the entire arrangement and form the wafer boat 100.

The wafer boat 100 can be used in the same way as a classical wafer boat or also in the form described hereafter, when the spacers are electrically conductive, such as the spacers 22 in the case of wafer boat 1. Electrical connection with the wafer pairs W, W which are situated on the supports 102, 104 takes place only in the region of the respective silts 112. The wafer boat 100 does not take up the wafers between plates, but leaves them substantially free-standing. This allows an improved heating of the wafers. This is additionally promoted by means of a reduced thermal mass of the wafer boat 100 in comparison with wafer beat 1. The back-to-back arrangement of the wafer pairs can contribute to improved lack of slippage of processed wafers. In addition, where appropriate, the lateral dimensions of the wafer boat can be decreased while maintaining the same capacity.

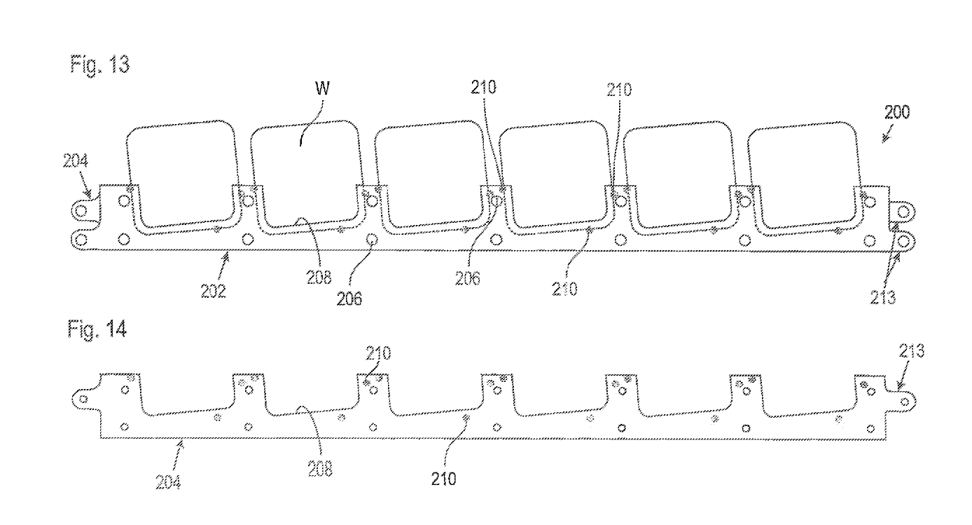

With the help of FIGS. 13 and 14, a further alternative embodiment of a wafer boat 200 will be described in more detail, which can be used in a plasma treatment apparatus 30 of the above-described type but also in classical plasma treatment apparatuses. FIG. 13 shows a schematic side view of a loaded wafer boat, and FIG. 14 shows a schematic side view of a single plate of the wafer boat. Generally, the wafer boat 200 is formed by electrically conductive plates 202, 204, which are made e.g. of graphite or another electrically highly conductive material, which are positioned alternatingly parallel to one another using spacers and clamp elements 206 which are not shown in more detail. This can be achieved in the manner described above, wherein the spacers can be made of a dielectric material or a high-resistance electrically conductive material, depending on whether they should perform an additional heating function or not, as will be described in more detail hereafter.

The plates 202, 204 each have recesses 208 which are open to the top. On both sides of the plates 202, 204 there is provided in the region of every recess a group of three carrier rods 210 which provide a three point support for the wafers to be supported, in each case, one of the carrier rods is below the recess 208 and two are on opposite sides of the recess 208 and higher than the lower carrier rod 210. The height difference between the lower carrier rod 210 and the upper edge of the plates 202, 204 is less than half the height of a wafer to be supported. Unlike in the case of wafer boat 1, the inserted wafers are not taken up entirely between two plates, but protrude clearly above the plates, as can be seen in FIG. 13. In comparison with wafer boat 1, wafer boat 200 has a substantially reduced thermal mass.

The plates 202, 204 each have at their ends contact nibs 213, wherein the contact nibs 213 of both plates in turn are located at different heights, in order to facilitate a group-wise contact of the plates by means of electrically conductive contact elements (not shown). The contact: nibs are preferably kept short and are rounded to the outside, in addition, the height distance between the contact nibs is shortened, which is of advantage when supplying them with a high-frequency voltage, in particular in MHz range, in particular when a coaxial supply is provided, as in the above-described plasma treatment apparatus 30.

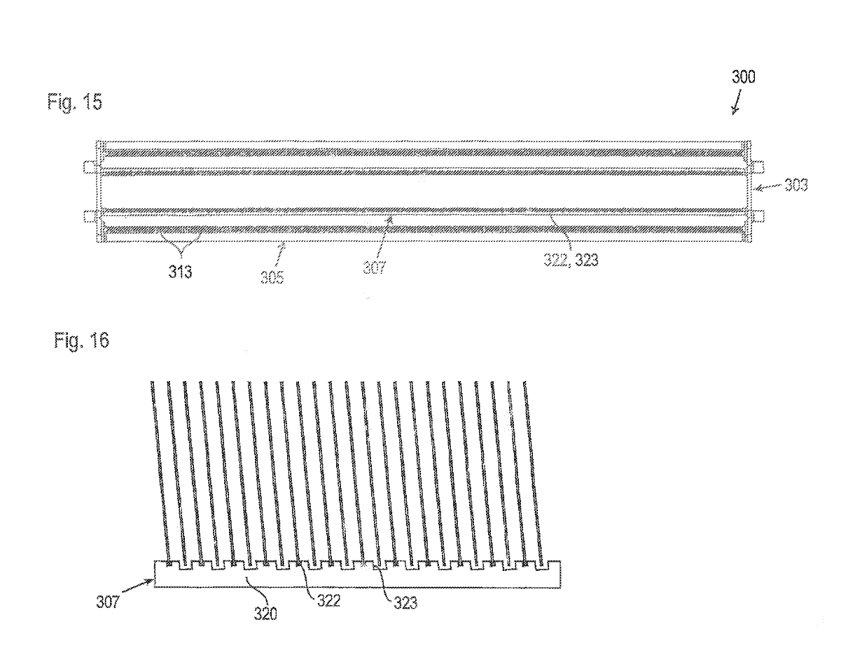

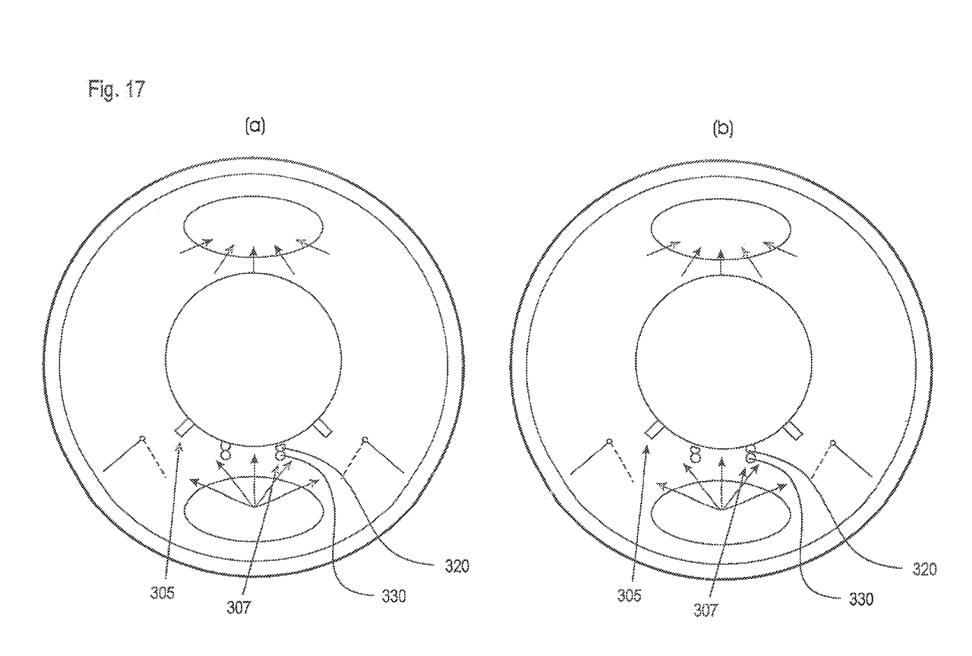

With the help of FIGS. 15 and 16, a further alternative embodiment of a wafer boat 300 will be described in more detail, which can be used in a plasma treatment apparatus 30 of the above-described type but also in classical plasma treatment apparatuses. FIG. 15 shows a schematic top view onto the wafer boat 300, FIG. 16 shows a schematic sectional view of a partial area of the wafer boat 300 and FIGS. 17(a) and (b) show schematic sectional views of a plasma treatment apparatus with a wafer boat 300. While the previously discussed wafer boats were each of the type in which the wafers are inserted parallel to the lengthwise extent of the wafer boat (and parallel to the lengthwise extent of the plasma treatment apparatus), wafer boat 300 is of the type in which the wafers are inserted transversely to the lengthwise extent of the wafer boat 300. In particular wafer boat 300 is of a classical construction such as is used in thermal diffusion systems for semiconductor wafers.

As can be seen in the top view according to FIG. 15, the wafer boat 300 has an elongated configuration: in other words, it is lengthwise (left-to-right in FIG. 15) substantially longer than in the other dimensions. At each end of the wafer boat 300 is provided an end plate 303 which is preferably made of quartz. It can however be made of another non-conductive material. Between the end plates 303 extend two carrier elements 305, which are spaced crosswise, and two spaced contact/guide elements 307 which are in each case attached to the end plates 303. The contact/guide elements 307 are situated crosswise between the carrier elements 305.

The carrier elements 305 extend, as previously mentioned, between the end plates 303 and are attached to them, in particular by welding or bonding. The carrier elements 305 can also be made of quartz and are of an elongated rod shape. The carrier elements 305 have a substantially rectangular profile, although “substantially” should also include rectangles with rounded corners. It would also however be generally possible for the carrier elements 305 to be round or of other shapes in profile. The substantially rectangular carrier elements 305 are positioned inclined towards one another, and each have on their narrow side pointing upwards a plurality of carrier slits 313, which extend crosswise to the lengthwise extension of the carrier element 305 and preferably substantially at an angle of 90° to the lengthways extension. The carrier silts 313 are in each case positioned at the same distance from one another and they have a pro-determined (constant) depth for receiving therein an edge section of each wafer or wafer pair which is to be inserted, wherein the wafer pair can e.g. be inserted in a back-to-back arrangement in the slit. The depth should preferably be the same as the waste edge area of the wafer, or smaller. The carrier silts can be inclined in a lengthwise direction by 1° or 2°, so that a wafer or wafer pair which is inserted is positioned accordingly inclined to the vertical.

In the following, the contact/guide elements 307 will be described in more detail, wherein two of these elements are shown in the top view according to FIG. 15. The contact/guide elements 207 comprise substantially a rod-shaped element 320 made of an electrically conductive material such as e.g. graphite, the ends of which are electrically contestable in a suitable way, which is net shown here.

The rod-shaped elements 320 each have a substantially round cross section, as can best be seen in the sectional view according to FIG. 17. In each rod-shaped element 320 is provided a plurality of slits 322 (contact slit) and slits 323 (insulating slit), which alternate in a lengthwise direction, as can best be seen in FIG. 16. The slits 322 each have a first depth and a first width, and slits 323 have a second depth and a second width, wherein the second depth is larger than the first, and the second width is larger than the first, as will be described in more detail hereafter. The slits 322, 323 are spaced identically to the silts 313 of the carrier elements 303, which means here the respective distance from the slit middle of each slit to the slit middle of the next slit. The slits 322, 323 in the spaced contact/guide elements 307 are offset from one another. In addition, the slits 313, 322 and 323 are positioned together in such a way that a wafer (or a wafer pair) inserted into the wafer boat is in each case inserted into two silts 313 (the spaced carrier elements), one slit 322 (of a contact/guide element 307), and one silt 323 (of the other contact/guide element 307). The depth and width of the slit 322 is selected so as to allow the wafer (or wafer pair) to contact the contact/guide element 307 reliably. The depth and width of the slit 323 is selected so as to make sure that the wafer (or wafer pair) definitely does not come into contact with the contact/guide element 307, as is indicated in FIG. 16.

Hereby it is ensured that adjacent wafers (wafer pairs), which are inserted into silts in the wafer boat which are lengthwise adjacent, contact different contact/guide elements. This is e.g. indicated in FIGS. 17(a) and (b) which e.g. show cross-sectional views through adjacent slits in the wafer boat. The cross section in the view according to FIG. 17(a) is located such that it intersects a slit 322 in the left contact/guide element 307 and a silt 323 in the right contact/guide element 307. Accordingly, in the case of the adjacent silt (view FIG. 17(b)), a slit 323 is intersected in the left contact/guide element 307 and a slit 322 is intersected in the right contact/guide element 307. The skilled person will recognize that a voltage can be applied between the wafers when a voltage is applied between the contact/guide elements 307. Although it is not shown in FIG. 16, insulating inlays can be set into each silt 323 which themselves have corresponding slits for the wafer (wafer pair), or the silts 323 can have an insulating coating. In particular, it is possible to form the slits 323 first in the contact/guide element 307, and then to apply an insulating coating, which is then locally destroyed when the slit 322 is formed in the following. In this way the electrical contact with the wafers is possible only in the region of the slits 322.

The contact/guide elements 307 can be quit(c) thinly constructed. However, in order to ensure a sufficient stability throughout the entire length of the wafer boat, there is a second red-shaped element 330 provided in the shown embodiment of the wafer boat 300, which is positioned vertically below the contact/guide elements 307 and extends between the end plates 303. The element 330 is preferably made of an electrically insulating material with sufficient stability to prevent contaminants from entering the process and with a sufficient thermal stability, such as e.g. quartz or another suitable material. The contact/guide element 307 can be disposed directly onto element 330, as shown, or there can be a plurality of supports provided between the lower element 330 and the contact/guide element 307. The lower element 330 can in its turn have a round form, but does not have a slit and has for this reason a higher stability than a similar element with slits, and it can for this reason support the contact/guide element 307 over its entire length.

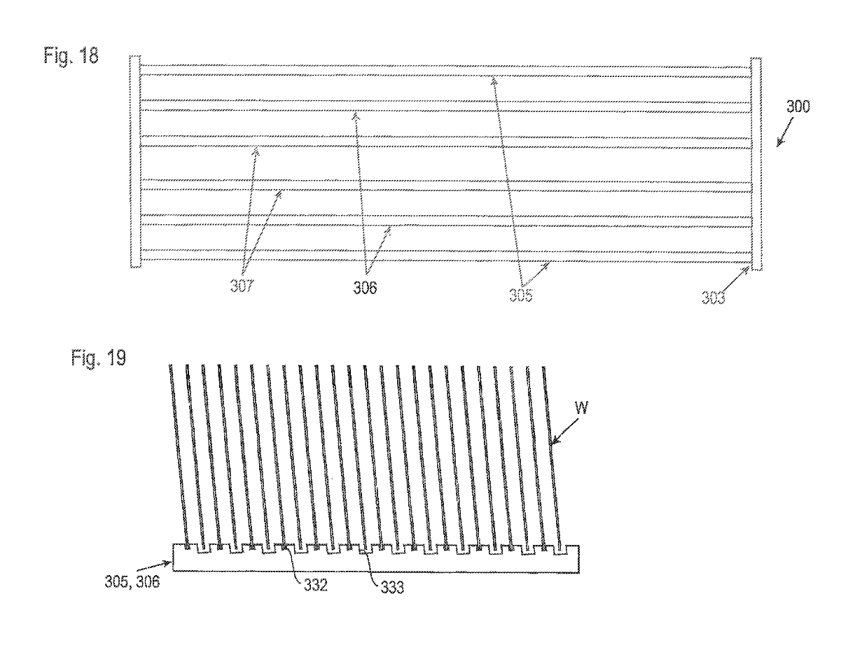

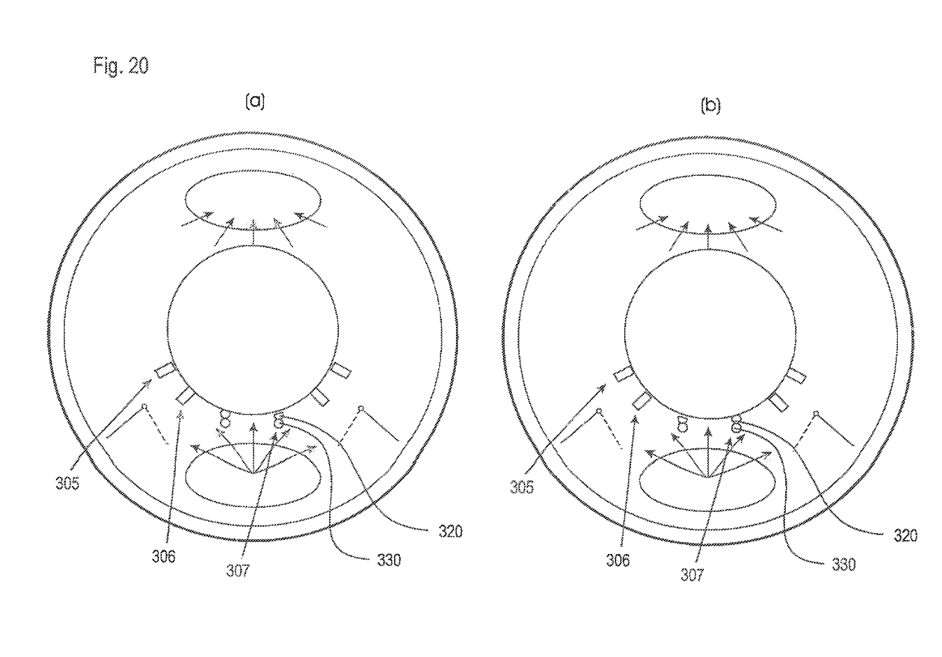

FIGS. 18-20 show a further alternative embodiment of a wafer boat 300. This wafer boat 300 is for the main part identical to the wafer boat 300 described in FIGS. 15-17, and for this reason the same reference signs are used for identical or similar elements. FIG. 18 shows a schematic top view onto the wafer boat 300, and FIG. 19 shows a schematic cross-section of a partial area of the wafer boat 300, and FIGS. 20(a) and (b) show schematic cross-sectional views of a plasma treatment apparatus with such a wafer boat 300. Also in the case of this wafer boat, the wafers are introduced transversely to the lengthwise extent of the wafer boat 300.

As can be seen in the top view according to FIG. 18, the wafer boat 300 has in turn an elongated configuration, wherein an end plate 303 is provided at each end of the wafer boat 300, which can be formed as previously described. Between the end plates 303 extend in each case two first carrier elements 305 spaced crosswise, two second carrier elements 307 spaced crosswise, and two spaced contact/guide elements 307 which are in each case attached to the end plate 303. Herein the contact/guide elements 307 are situated crosswise between the second carrier elements 306, and the second carrier elements 306 are situated in each case between one first carrier element 305 and one contact/guide element 307.

The contact/guide elements 307 have the same construction as previously described, with upper and lower rod elements 320, 330 and contact slits 222 and insulating slits 223, which are positioned offset from one another in the respective contact/guide elements 307. This means that every second wafer inserted into the wafer boat will be contacted by one of the contact/guide elements 307, while the other wafers will be contacted by the other contact/guide element.

The first and second carrier elements 305, 306 extend between the end plates 303 and are attached to these plates as described above. The first and second carrier elements 305, 306 can also be made of quartz and are both of elongated rod-shape. The first and second carrier elements 305, 306 both have a basic shape, such as can be seen in the case of wafer boat 300 in FIGS. 15-17. Each of them also has a plurality of silts 330 corresponding to the plurality of carrier slits 313 according to FIG. 16-17. The silts 330 are in the form of two types of slit, which differ with respect to their size and function.

The first type of silt, which serves as carrier sill 332, has a first depth and a first width which are suitable for receiving in the silt in a contacting manner the edge area of an inserted wafer or wafer pair, for example in a back-to-back manner. Preferably, the depth of the slit is approximately equal to or smaller than the waste edge area of the wafer. The second type of silt, which serves as an insulating slit 333, has a second depth and a second width which are in each case greater than the first depth and first width. The insulating silts 333 are in each case suitable for receiving an edge area of an inserted wafer or wafer pair standing freely, in other words, without contact.

The carrier slits 332 and the insulating silts 333 alternate along the lengthwise direction of the carrier elements 305, 306, as can be seen in the view in FIG. 19. The carrier slits 332 and the insulating slits 333 of the first carrier elements 305 are aligned to one another. Also, the carrier slits 332 and the isolating slits 333 of the second carrier elements 306 are aligned to one another, in addition, the carrier slits 332 of the first carrier elements 305 are aligned to the insulating slits 333 of the second carrier elements 306, and the insulating slits 333 of the first carrier elements 305 are aligned to the carrier slits 332 of the second carrier elements 306. In other words, the carrier slits and insulating slits 332, 333 of the first carrier elements 305 are offset from the carrier silts and insulating slits 332, 333 of the second carrier elements 306.

In this way, every second wafer inserted into the wafer boat is inserted into and supported by the first carrier elements 305, while the other wafers are inserted into and supported by the second carrier elements 306. Hereby it is also achieved that all wafers which are inserted into and supported by the first carrier elements 305 contact the same contact/guide element 307, while the other wafers which are inserted into and supported by the second carrier elements 306 contact the other contact/guide element 307. A correspondingly alternating supporting and contacting is indicated in FIGS. 20(a) and (b). This configuration can during operation prevent a short circuit by means of the first and second carrier elements 305, 306 in the case that during a plasma treatment (of which the object is to precipitate e.g. conductive coatings onto the wafers) conductive coatings are precipitated onto the first and second carrier elements 305, 306.

In this configuration it would also be possible to provide conductive first and second carrier elements 305, 300 and additionally to apply a current between the wafers inserted into the wafer boat 300, in order to increase the contact surface to the wafers and the surface for the transmission of electrical current.

Hereafter the operation of the plasma treatment apparatus 30 will be described in more detail with reference to the drawings, wherein a plasma-supported precipitation of silicon nitride or aluminium oxide in a plasma induced by 13.56 MHz is used as an example of a plasma treatment. The treatment apparatus 30 can however also be used for other precipitation processes which are also plasma-supported, wherein the plasma can also be induced by other frequencies, e.g. those in the range of 40 kHz. The coaxial cable 74 is, however, particularly suitable for frequencies in the MHz range and optimised for these.

First, it will be assumed that a loaded wafer boat 1 of the type described above (according to FIG. 1) is inserted into the process chamber 38, and that the chamber is closed by means of the shutting mechanism (not shown). Herein, the wafer boat 1 is loaded in such a manner that in each carrier slit 11 there are in total 12 wafers, in the present example in particular silicon wafers; particularly six wafers at each plate 6. The wafers are inserted in such a way that they face each other in pairs, as is well known in this field of technology.

In this condition, the interior room is at ambient pressure and can e.g. be purged or flooded with N₂ by the gas control unit 60 (in combination with the negative pressure control unit 62).

The tube element 36 and therewith the process chamber 38 are heated up by the net shown heating device, in order to warm up the wafer boat 1, and the wafers inserted into it, to a pre-determined temperature which is advantageous for the process. The deflection elements are in the second position (shown in dashed lines in FIG. 5) in order not to affect heating by means of convection. Nevertheless, heating the inboard plates of the wafer boat 1 and the wafers situated between the plates can take a long time using a heating of the tube element 36.

For this reason, when a wafer boat 1 of the type described above is provided, a DC current or a low-frequency AC current can be applied by the electrical control unit 64 to the wafer boat 1 to support the heating process. The voltage is in this case sufficiently high to allow electrical current to be conducted through the high-resistance spacer elements 22 and to allow these to function as resistance heating elements. In this way, heating power is provided specifically in the carrier silts 11, so that the pre-determined temperature can be reached much quicker than would be the case with heating from outside. Depending on the resistance of the spacing elements, voltages of at least 200 V to approximately 1 kV are considered, in order to achieve a sufficient flow of electrical current and a sufficient heating of the spacing elements 22.

When the pre-determined temperature of the wafer boat 1 and therewith the entire unit (wafer boat 1, wafers and tube element 36) has been achieved, the electrical control unit 64 can first be deactivated, and the process chamber is pumped to a pre-determined negative pressure by the negative pressure control unit 62. The deflection elements 50 are automatically moved into the first position (solid line in FIG. 5) by the negative pressure being set, or are actively moved into the first position. When the pre-determined negative pressure has been reached, a desired process gas, such as e.g. SiH₄/NH₃ for a silicon nitride precipitation, in defined proportions, dependent on the desired coating properties, is let in by means of the gas control unit 60, while the negative pressure is maintained by the negative pressure control unit 62 by pumping out the introduced process gas. The process gas pumped out by the pump 70 can be diluted with N₂ at this point in time, as is well known in this field of technology. For this purpose, N₂ is added by means of the gas control unit 60 and the appropriate pipe from the pump. By means of the special arrangement of the gas pipes 44, 46 in combination with the deflection elements 50, a gas flow within the process chamber is primarily generated through the carrier slit 11 of the wafer boat 1. This can be ensured to be homogeneous throughout the width and length of the wafer boat by means of the special arrangement of the gas pipes 44, 46.

By means of the electrical control unit 64, a high-frequency voltage with a frequency of 13.56 MHz is applied to the wafer boat 1. This results in a plasma ignition of the process gas between the plates 6 and in particular between the wafers inserted in wafer boat 1 and results in a plasma-supported silicon nitride deposition onto the wafers. The gas flow is kept constant during the deposition process, in order to avoid a local depletion of the active components of the process gas. When the time required for deposition of the requisite thickness of coating has elapsed, the electrical control unit is again deactivated, and the gas supply is stopped, or switched back to supplying Ns in order to purge the process chamber 38 and if necessary to ventilate it (returning it to atmospheric pressure). Finally, the process chamber 38 can then be brought back to environmental pressure.

As can be seen from the above description, the wafer boat 1 of the above type—independently of the other components of the treatment apparatus—offers the advantage of allowing, during the heating phase, to heat up directly in the region of the carrier slits 11 between the plates 6 of the wafer boat 1. This is possible by means of the electrically conductive spacing elements 22. Since they have been specifically selected for being highly resistant, they do not significantly affect the plasma generation when a high-frequency current is applied.

The specific gas supply by means of the gas supplies 44, 46 offers the advantage—again independently of the other components of the treatment apparatus, including the special wafer boat 1—of a homogeneous gas flow in the process chamber 38. In particular in combination with the deflection elements, a targeted gas flow through the carrier silts can be achieved. This guarantees a good gas exchange and a homogeneous gas distribution in the process chamber and, where applicable, lower flow rates can be used for the process gases.

The specific coaxial cable 74 allows the advantage—again independently of the other components of the treatment apparatus, including the special wafer boat 1 with electrically conductive spacing elements 22 or the special gas supply—that voltages in the MHz range (and particularly of 13.56 MHz) can be efficiently applied to the wafer boat. Electrical losses can be reduced. This is enhanced by the specific design of the contact areas of the wafer boat 1, such as the dimensions and shape of the contact nibs.

The wafer boats 100, 200 and 300 provide a substantially lower thermal mass than wafer boat 1, and the substantially free-standing wafers can be more easily heated. In the region of the supports 102. 104 and the plates 202, 204, electrically conductive spacers can be used, in order to provide here during the heating phase a local additional heating. In particular, the thermal mass of the supports and the plates can be balanced out, which is not possible in a free-standing wafer region. The wafer boat 300 allows another layout of wafers, which, in particular in the case of an unchanged process chamber allows the insertion of bigger wafers. The treatment apparatus 30 and the wafer boat 1 have been described by means of specific embodiments of the invention with reference to drawings, without being limited to the specifically shown embodiments. In particular, the gas supplies 44, 46 could be of different shapes or could be arranged differently, as is also indicated in FIGS. 7-9. Also plates 6 of the wafer boat 1 can have other dimensions and in particular can be dimensioned for holding another number of wafers. The treatment apparatus is shown in a horizontal orientation and this represents a preferred design. However, most of the advantageous aspects of the present application are also valid for a vertical chamber with a vertically positioned tube element, wherein in this case position references such as above, below should be changed accordingly to lateral position references. This is particularly valid for the gas supply pipes with reference to the wafer boat and a mounting space for these pipes.

1. A plasma treatment apparatus for wafers, in particular for semiconductor wafers for semiconductor or photovoltaic applications, which comprises the following:
a processing room for holding a wafer boat, the wafer boat having a plurality of electrically conductive carrier elements for the wafers;
means of controlling or regulating a process gas atmosphere in the processing room; and
at least one voltage source which can be connected with the wafer boat by means of a cable fed into the processing room, wherein the cable is in the form of a coaxial cable with an inner conductor and an outer conductor, and wherein a dielectric is provided between the inner conductor and the outer conductor in such a way that, when a high-frequency voltage is applied, the propagation speed and the wavelength of the electromagnetic wave in the coaxial cable is reduced as opposed to the propagation speed and the wavelength of the electromagnetic wave in a vacuum.

2. Plasma treatment apparatus according to claim 1, wherein the geometric length of the coaxial cable is nearly an odd-numbered multiple of λ/4 of the wavelength which is reduced by the dielectric.

3. Plasma treatment apparatus according to claim 1, wherein the dielectric is formed of a plurality of dielectric elements.

4. Plasma treatment apparatus according to claim 1, wherein the dielectric is formed of a plurality of dielectric elements with differing dielectric constants.

6. Plasma treatment apparatus according to claim 1, wherein the at least one voltage source is of the type which is suitable for generating a high-frequency AC current, in particular with a frequency in the MHz range, and particularly in the range of 13.56 MHz.
